(19) United States
(12) Patent Application Publication
(10) Pub. No.: US 2008/0157346 A1
(43) Pub. Date: Jul. 3, 2008

(54) Method for fabricating heat-dissipating package and heat-dissipating structure applicable thereto

(75) Inventors: Min-Shun Hung, Taichung Hsien (TW); Ho-Yi Tsai, Taichung Hsien (TW); Chien-Ping Huang, Hsinchu Hsein (TW); Chun-Ming Liao, Taichung Hsien (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/796,320

(22) Filed: Apr. 26, 2007

(30) Foreign Application Priority Data
Dec. 29, 2006 (TW) 095149739

(51) Int. Cl. H05K 7/20; H01L 21/58

(52) U.S. Cl. 257/712; 438/122; 257/E23.08; 257/E21.505

(57) ABSTRACT

A method for fabricating a heat-dissipating package and a heat-dissipating structure applicable thereto are disclosed. The method includes: mounting and electrically connecting to a chip carrier a semiconductor chip mounted with a heat-dissipating structure; disposing on the heat-dissipating structure a covering layer protrudingly formed with an abutting portion surrounding the covering layer, wherein the size of the heat-dissipating structure is greater than the predetermined one of the package to position the chip carrier in a cavity of a mold and encapsulate the heat-dissipating structure and semiconductor chip by encapsulant, and the protruding portion abuts against a top surface of the cavity and prevent the heat-dissipating structure from warping; and singulating the package and removing the encapsulant from the covering layer thereunder according to the predetermined size of the package.

### FIELD OF THE INVENTION

The present invention is related to methods for fabricating semiconductor packages, and more particularly, to a method for fabricating heat-dissipating packages and the heat-dissipating structure applicable thereto.

### BACKGROUND OF THE INVENTION

In order to make a semiconductor package slimmer in size and volume, it is essential to be capable of manufacturing the semiconductor package with a high density of electrical components and circuits. Yet, such kind of semiconductor package could also generate more heat during operation. Therefore, if the heat generated by a semiconductor chip is not dissipated fast enough, the heat accumulated in the semiconductor package could jeopardize the electrical performance of the semiconductor chip and the reliability of semiconductor package severely. Moreover, in order to prevent contamination and entry of humidity or dusts from external environment, surfaces of the semiconductor chip are covered and isolated by a packaging encapsulant. However, the packaging encapsulant is generally made of a resin that has poor thermal-conductivity, as the heat transfer coefficient of the resin is about 0.8 w/mK. Consequently, heat generated by electrical components and circuits deployed on an active surface of the semiconductor chip cannot be efficiently dissipated to external environment via the packaging encapsulant, and thus a large amount of heat will accumulate within the semiconductor package, thereby resulting in damages to the chip and a reliability issue of the semiconductor package. Accordingly, in order to improve efficiency of heat dissipation, a solution utilized by the industry is to employ a heat-dissipating member in the semiconductor package.

Still, because the heat-dissipating member is completely covered by the packaging encapsulant, the only heat-dissipating pathway for the heat generated by the semiconductor chip is to be dissipated through the packaging encapsulant, thereby limiting the improvements in heat dissipation and fails to meet the requirements for heat dissipation. Accordingly, in order to effectively dissipate heat generated by the chip, the heat-dissipating member has to be sufficiently exposed from the packaging encapsulant to directly dissipate the heat generated by the semiconductor chip to the ambience during operation.

As shown in FIG. 1, a structure of a semiconductor package from prior art, according to the U.S. Pat. No. 5,726,079, is disclosed. In order to be directly contacted with external environment, such a semiconductor package 1 from prior art employs a heat-dissipating plate 11, which attaches directly on a chip 10, to allow a top surface 11a of the heat-dissipating plate 11 to be exposed from the packaging encapsulant 12 covering the chip 10, so as to dissipate the heat generated by the chip 10 to the external environment via the heat-dissipating plate 11, without using the encapsulant 12 having a poor thermal conductivity.

Yet, fabrication of such semiconductor package 1 has several drawbacks. For instance, after the heat-dissipating plate 11 is attached to the chip 10, a molding process is performed, and the heat-dissipating plate 11 attached to the chip 10 is placed into a mold cavity of a mold to form the encapsulant 12. During the molding process, the top surface 11a of the heat-dissipating plate 11 should abut against a top surface of the mold cavity, in order to prevent the encapsulant from flushing over the top surface 11a of the heat-dissipating plate 11. Flushing as such not only decreases efficiency of heat dissipation of the heat-dissipating plate 11, but also forms an undesired appearance of the package, which requires extra post-treatment processes, such as deflashing to remove the encapsulant flushed over the top surface of the heat-dissipating plate. However, deflashing is an elaborate and time-consuming process, which often increases the cost of production and damages the product quite easily. In addition, if the heat-dissipating plate is abutted against the top surface of the mold cavity with excessive force, the chip 10 is easily damaged due to excessive stress applied thereto.

Moreover, in order to match the depth of the mold cavity to the distance between the top surface 11a of the heat-dissipating plate 11 and the top surface of a substrate 13, the adhesive layer between the heat-dissipating plate 11 and the chip 10, the adhesive layer between the chip 10 and the substrate 13, and the thickness of the heat-dissipating plate 11 must be precisely calculated, controlled and fabricated. To meet the aforementioned precision requirements, the complexity of fabrication has to be increased to a certain level, with an increase in cost of production. Therefore, it is quite impractical and inefficient to use such a fabrication method due to the increase of fabrication complexity of and cost of production.

Referring to FIGS. 2A and 2B, a heat-dissipating semiconductor package, according to the U.S. Pat. No. 6,458,626, which is filled and invented by the inventor(s) of the present invention, is disclosed to solve and/or improve the foregoing drawbacks of the prior arts. The U.S. Pat. No. 6,458,626 discloses a heat-dissipating package formed with a heat-dissipating plate 21, wherein the heat-dissipating plate 21 can be directly mounted on a chip without damaging the chip 20 or having an encapsulant 24 flushing over a top surface of the heat-dissipating plate 21. Furthermore, a surface of the heat-dissipating plate 21, which is to be exposed to the external environment, has a covering layer 25 formed thereon, wherein the covering layer 25 is a layer of gold (such as a plated Au), and is characterized by having poor adhesion with the encapsulant 24. Then the heat-dissipating plate 21 is directly mounted on a chip 20 disposed on a substrate 23. Later, a molding process is performed to form the encapsulant 24 that fully covers the heat-dissipating plate 21 and the chip 20, wherein a portion of the encapsulant 24 is also formed on the covering layer 25 applied on the heat-dissipating plate 21 (as shown in FIG. 2A), such that the depth of a mold cavity is larger than a summation of thicknesses of the chip 20 and the heat-dissipating plate 21. Therefore, the heat-dissipating plate 21 will not be squeezed or damaged by the mold when the mold is clamped. A singulation process is then performed to form a molded structure with a predetermined size, followed by removing of the portion of the encapsulant 24 formed on the heat-dissipating plate 21. As the adhesive force between the covering layer 25 and the heat-dissipating plate 21 is greater than that between the covering layer 25 and the encapsulant 24, the covering layer 25 can remain on the heating-dissipating plate 21. In other words, due to the poor adhesion between the covering layer 25 and the encapsulant 24, the portion of the encapsulant 24 can be completely removed with no residue left on the covering layer 25 (as shown in FIG. 2B), such that the heat generated by the chip 20 during operation can be efficiently dissipated via the heat-dissipating plate 21 and the covering layer 25, without encountering flushing problems. Similar structural designs and methods for fabricating the same are described in U.S. Pat. Nos. 6,844,622 and 6,444,498, and thus there is no need to further discuss hereinafter.

Referring to FIG. 3, a semiconductor package is fabricated according to the aforementioned prior-art methods. However, as illustrated in FIG. 3, in the case that the heat-dissipating plate 31 of the semiconductor package in the prior art is made oversized, when the substrate 33 attached to the chip 30 and the heat-dissipating plate 31 are placed in the mold cavity 360 of the mold 36 during molding process, the space above the heat-dissipating plate 31 is usually smaller than that beneath the heat-dissipating plate 31. In other words, the space beneath the heat-dissipating plate 31 provides more room for the mold flow to pass through easily, whereas the space above the heat-dissipating plate 31 hinders to a certain extent the movement of the mold flow with less room is available. As a result, speed of the mold flow below the heat-dissipating structure 31 (hereinafter referred as the bottom mold flow) is relatively faster than the mold flow thereabove (hereinafter referred as the top mold flow of the heat-dissipating structure 31). This thereby creates an unbalanced force between the bottom mold flow and the top mold flow, and accordingly causes the heat-dissipating structure 31 to warp upward, whereby forming an undesirable appearance, and moreover, causing delamination of the heat-dissipating structure 31 from the chip 30 by damaging the adhesion therebetween, or affecting quality of electrical connection between the chip 30 and the substrate 33 by damaging/cracking solder bumps implanted for electrically connecting the flip chip to the substrate.

Moreover, if the space above the heat-dissipating plate is adjusted and modified to provide more room for the mold flow to flow through, the amount of the packaging encapsulant used above the heat-dissipating plate will be increased. However, as the packaging encapsulant above the heat-dissipating plate must be removed in subsequent processes, such an increase of packaging encapsulant above the heat-dissipating plate not only wastes fabrication materials but also increases fabrication cost.

Accordingly, there still remains a need for providing a method for fabricating a heat-dissipating package and a heat-dissipating structure applicable thereto, which is not merely capable of avoiding damaging the semiconductor chip and flushing during the molding process, but also preventing warpage of the heat-dissipating structure during the molding process, to prevent delamination of the heat-dissipating structure from the chip to ensure quality of electrical connection between the chip and the substrate, as well as avoiding wasting fabrication materials and increasing fabrication cost.

### SUMMARY OF THE INVENTION

In light of the shortcomings of the above prior arts, the primary objective of the present invention is to provide a method for fabricating a heat-dissipating package and a heat-dissipating structure applicable thereto, which can prevent warpage of a heat-dissipating structure during molding processes, so as to avoid delamination of a heat-dissipating structure from a chip and to ensure quality of electrical connection between a chip and a chip carrier.

Another objective of the present invention is to provide a method for fabricating a heat-dissipating package and a heat-dissipating structure applicable thereto, which can prevent an increase in fabrication cost and the amount of material used.

A further objective of the present invention is to provide a method for fabricating a heat-dissipating package and a heat-dissipating structure applicable thereto, without damaging chip and flushing during a molding process, so as to improve yield of production.

To attain the above and other objectives, the present invention is to provide a method for fabricating heat-dissipating packages, and the method comprises the steps of: mounting and electrically connecting a semiconductor chip to a chip carrier; attaching a heat-dissipating structure to the semiconductor chip, wherein the heat-dissipating structure comprises a main body having a first surface that has a covering layer formed thereon, a second surface opposite to the first surface, and a plurality of protruding portions from and formed at edges of the main body, wherein a size of the heat-dissipating structure is larger than a predetermined size of the package, such that the edges of the main body of the heat-dissipating structure outwardly extend beyond corresponding sides of the semiconductor chip, after the heat-dissipating structure is attached to the semiconductor chip via the second surface of the main body thereof; performing a molding process to form an encapsulant covering the heat-dissipating structure and the semiconductor chip, wherein the molding process includes disposing the chip carrier mounted with the semiconductor chip and the heat-dissipating structure into a mold cavity of a mold, filling the mold cavity with an epoxy mold compound (EMC) material to form the encapsulant, and removing the mold; performing a singulation process to form the package with the predetermined size; and performing a removing process to remove a portion of the encapsulant formed on the covering layer. Furthermore, in one embodiment, the covering layer may be a metal layer made of gold or nickel, so as to make an adhesive force between the covering layer and the heat-dissipating structure greater than an adhesive force between the covering layer and the encapsulant, thereby allowing a portion of the encapsulant formed on the covering layer to be easily removed during a removing process to expose the covering layer to the ambience. Accordingly, the heat generated by the chip can be effectively dissipated to external environment via the heat-dissipating structure and the covering layer. In another embodiment, the covering layer may be selectively made of at least one of a film, an epoxy material, and an organic layer, so as to make the adhesive force between the covering layer and the encapsulant greater than the adhesive force between the covering layer and the heat-dissipating structure, as an alternative to the aforementioned, thereby allowing the covering layer and the portion of the encapsulant formed on the covering layer to be removed at once during the removing process. As a result, the first surface of the main body of the heat-dissipating structure is exposed to the ambience, and therefore the heat generated by the semiconductor chip can be effectively dissipated.

Accordingly, the present invention purposes a method for fabricating a heat-dissipating package and a heat-dissipating structure applicable thereto. The heat-dissipating structure is attached to a semiconductor chip, and is formed with a covering layer on a surface thereof. Moreover, edges of the heat-dissipating structure are formed with a plurality of protruding portions upwardly protruded from the main body, and a size of the heat-dissipating structure is larger than a predetermined size of a heat-dissipating package. Thus, if the heat-dissipating structure is to be upwardly pushed by the bottom mold flow when the bottom mold flow below the heat-dissipating structure flows faster than the top mold flow thereabove, the protruding portions formed at the edges of the main body of the heat-dissipating structure can be abutted against the top surface of the mold cavity to avoid warpage of the heat-dissipating structure, at the time the chip carrier mounted with the semiconductor chip and the heat-dissipating structure thereon is placed in a mold cavity of a mold to be filled with EMC during a molding process. Therefore, the present invention not only prevents warpage of the heat-dissipating structure and delamination of the heat-dissipating structure from the chip, but also improves the quality of electrical connection between the chip and the chip carrier without enlarging the mold cavity. Consequently, arrangement and design of the present invention also reduce the amount of material used and the cost of production. Once an encapsulant is formed, which covers the heat-dissipating structure and the chip, the mold is then removed and the packaged structure is singulated according to a predetermined size. Subsequently, the portion of the encapsulant formed on the covering layer is removed, to form the heat-dissipating package integrated with the heat-dissipating structure.

Certain embodiments of the invention have other aspects in addition to or in place of those mentioned above. The aspects will become apparent to those skilled in the art from the following detailed description when taken with reference to the accompanying drawings.

### BRIEF DESCRIPTION OF THE DRAWINGS

The present invention can be more fully comprehended by reading the detailed description of the preferred embodiments listed below, with reference made to the accompanying drawings, wherein:

FIG. 1 (Prior Art) is a schematic view showing a heat-dissipating semiconductor package according to the U.S. Pat. No. 5,726,079;

FIGS. 2A and 2B (Prior Art) are schematic views showing a heat-dissipating semiconductor package according to the U.S. Pat. No. 6,458,626;

FIG. 3 (Prior Art) is a schematic view showing a heat-dissipating semiconductor package of the prior-art having a warpage problem during a process;

FIGS. 4A to 4F are schematic views showing a method for fabricating a heat-dissipating package and a heat-dissipating structure applicable thereto according to a first embodiment of the present invention;

FIG. 5 is a schematic view showing a heat-dissipating structure fabricated according to a second embodiment of the present invention;

FIG. 6 is a schematic view showing a fabrication method of a heat-dissipating package according to a second embodiment of the present invention; and

FIG. 7 is a schematic view showing a fabrication method of a heat-dissipating package according to a third embodiment of the present invention.

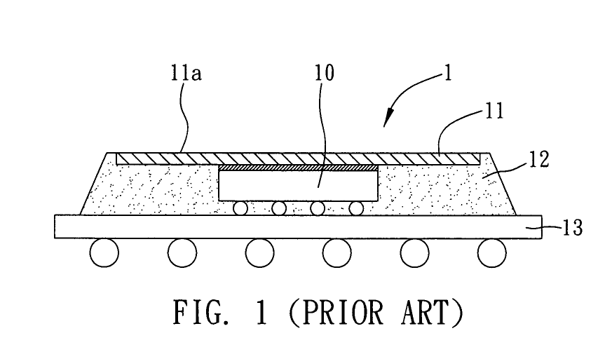

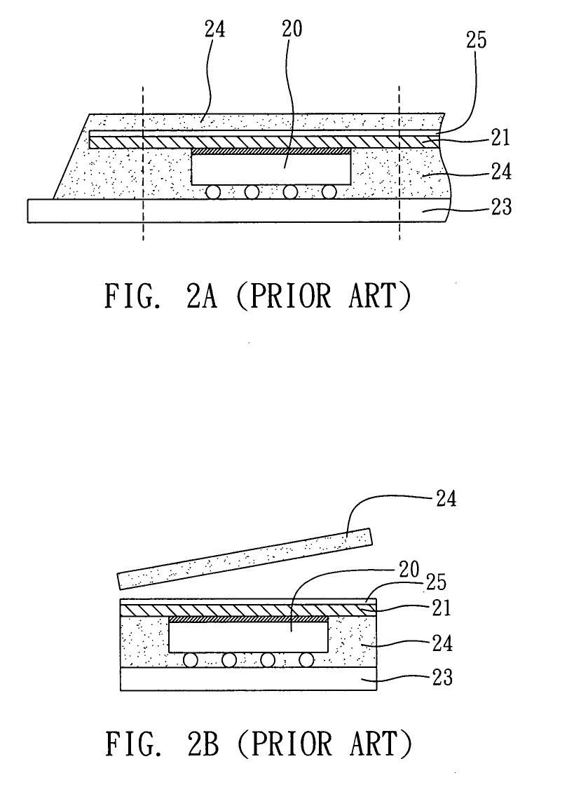

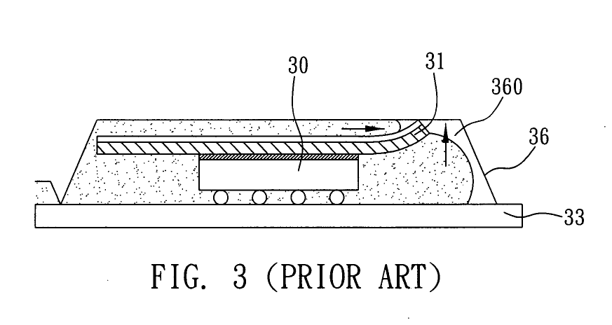

### DETAILED DESCRIPTION OF THE PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

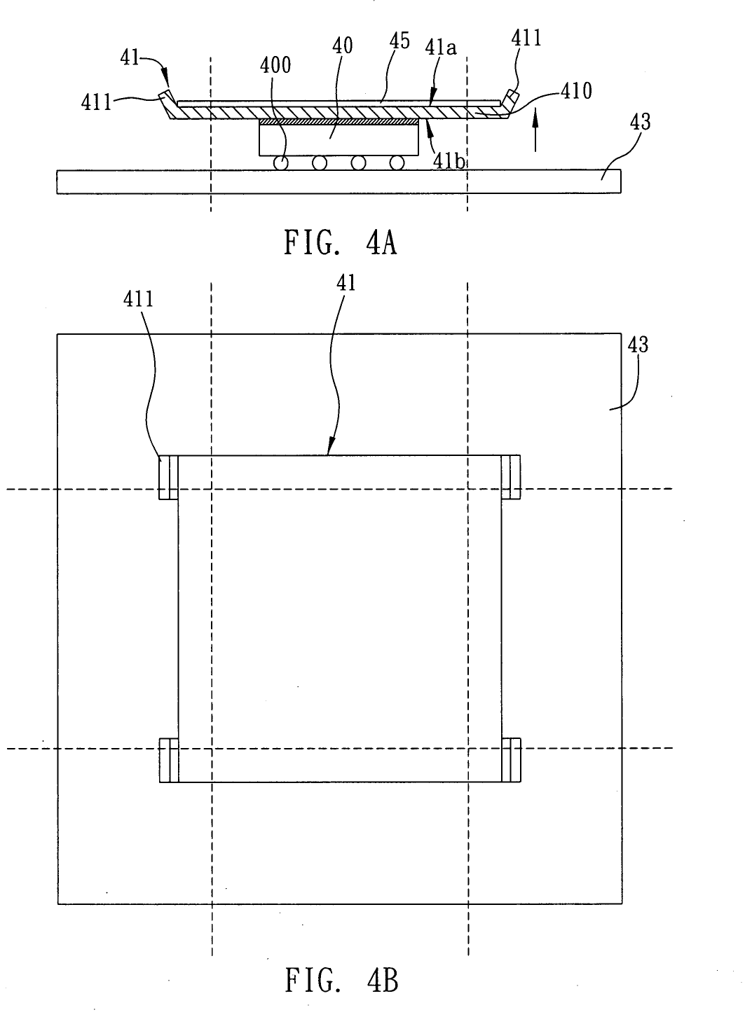

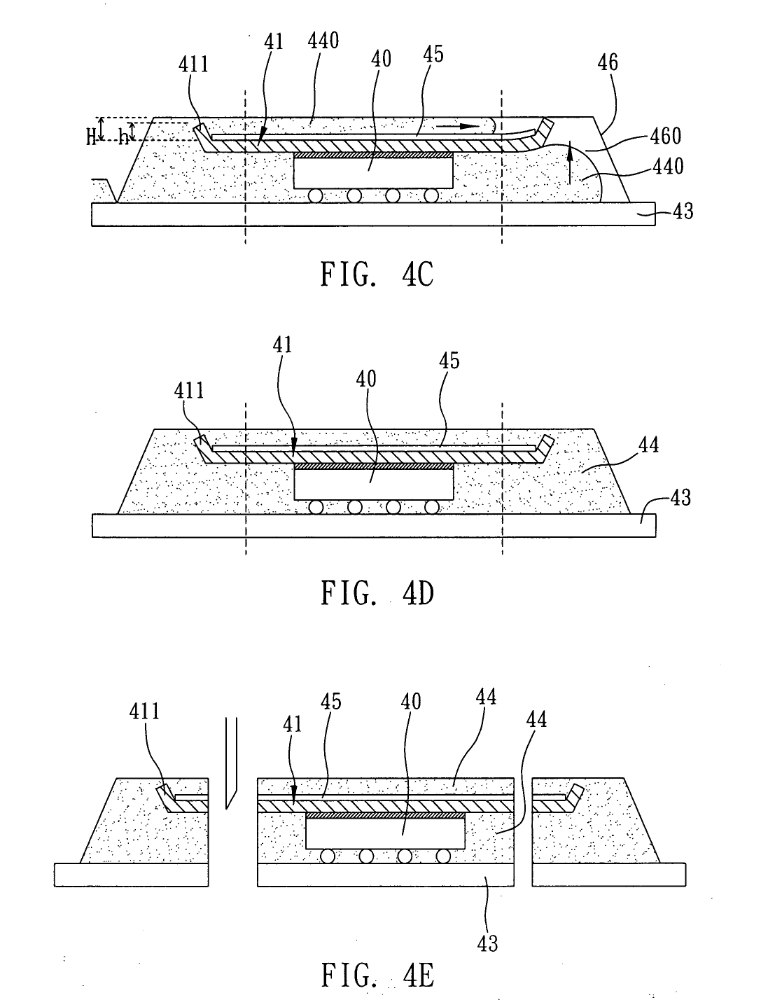

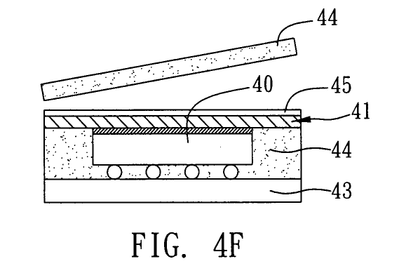

FIGS. 4A to 4F are schematic views showing the procedure steps of a fabrication method of a heat-dissipating package and a heat-dissipating structure applicable thereto according to a first embodiment of the present invention. The fabrication method of the present invention may be applied to a single chip carrier, or to a batch module with a plurality of chips, according to demand. It should be noted that the drawings have been simplified in order to elucidate the heat-dissipating package of the present invention; the drawings only show the components that are relevant to the present invention, and the shape and size of the shown components are not necessarily identical to that of the actual embodiment. The quantity, shape, and size ratio of components in actual embodiment can be designed selectively, and the allocation of the components could be more sophisticated.

As shown in FIGS. 4A and 4B, a semiconductor chip 40 is mounted and electrically connected to a chip carrier 43, and a heat-dissipating structure 41 is disposed on the semiconductor chip 40. The heat-dissipating structure 41 comprises a main body 410 having a first surface 41a and a second surface 41b opposite to the first surface 41a; and a plurality of protruding portions 411 upwardly protrudes from the first surface 41a and disposed at edges of the main body 410.

The first surface 41a of the heat-dissipating structure 41 is further covered by a covering layer 45. And the size of the heat-dissipating structure 41 is larger than the predetermined size of the package, so that the edges of the main body 410 of the heat-dissipating structure are allowed to outwardly extend beyond the corresponding sides of the semiconductor chip 40. Thus, it allows the protruding portions 411 to be positioned at areas outside the predetermined size of the package. In addition, the heat-dissipating structure 41 is attached to the semiconductor chip 40 via the second surface 41b thereof by the use of a thermal adhesive. (The borders of the predetermined size of the package are shown in dot lines in FIG. 4B, which is a top view of FIG. 4A.)

The chip carrier 43 may be at least one of a Ball Grid Array (BGA) substrate, a Land Grid Array (LGA) substrate and a lead frame. The semiconductor chip 40 may be a flip-chip type semiconductor chip, which is electrically connected to the chip carrier 43 via a plurality of conductive bumps 400.

The covering layer 45 may be made from any material as long as the adhesive force between the covering layer 45 and the heat-dissipating structure 41 is relatively greater than that between the covering layer 45 and the encapsulant used for encapsulating the heat-dissipating structure 41 and the semiconductor chip 40 (to be illustrated below). For example, the covering layer 45 may be a metal layer made of gold or nickel.

Referring to FIGS. 4C and 4D, a molding process is performed to form an packaging encapsulant 44 for encapsulating covering the heat-dissipating structure 41 and the semiconductor chip 40. First, the chip carrier 43 mounted with the semiconductor chip 40 and the heat-dissipating structure 41 is placed into a mold cavity 460 of a mold 46, and then the mold cavity 460 is filled with an EMC material 440, wherein the height h of each of the protruding portions 411 of the heat-dissipating structure 41 is set to be about 0.03˜0.1 mm shorter than the vertical distance H between the heat-dissipating structure 41 and a top surface of the mold cavity 460. In one preferred embodiment, the height h of each of the protruding portions 411 is preferably set to be 0.05 mm shorter than the vertical distance H between the heat-dissipating structure 41 and the top surface of the mold cavity 460. During the molding process, when a bottom mold flow below the heat-dissipating structure 41 runs faster than a top mold flow running thereabove, the heat-dissipating structure 41 tends to be upwardly pushed by the bottom mold flow. However, owing to the formation of the protruding portions 411 are upwardly protruded from the edges of the heat-dissipating structure 41, the protruding portions 411 can be abutted against the top surface of the mold cavity 460 accordingly, at the time the heat-dissipating structure 41 is lifted. Thus, said design and arrangement of the protruding portions 411 of the present invention can reduce and prevent warpage of the heat-dissipating structure 41.

Subsequently, the packaging mold 46 is removed and the encapsulant 44 formed on the chip carrier 43, allowing the encapsulant 44 to cover the heat-dissipating structure 41 and the semiconductor chip 40.

Then, as shown FIGS. 4E and 4F, a singulation process is performed to cut the chip carrier 43, the encapsulant 44 and an outer portion of the heat-dissipating structure 41 according to the predetermined size of the package. Furthermore, as the size the heat-dissipating structure 41 is larger than the predetermined size of the package, the protruding portions 411 formed at the edges of the heat-dissipating structure 41 can be removed during the singulation process.

In the last step, a removing process is performed to remove the portion of the encapsulant 44 formed on the covering layer 45. Moreover, in this particular embodiment, the covering layer 45 is a metal layer made of gold and/or nickel, so that the adhesive force between the covering layer 45 and the heat-dissipating structure 41 is relatively greater and stronger than the adhesive force between the covering layer 45 and the encapsulant 44, allowing the portion of the encapsulant 44 formed thereon to be easily removed in order to expose the covering layer 45. Therefore, the heat generated by the chip 40 can be effectively dissipated to external environment via the heat-dissipating structure 41 and the covering layer 45.

### Second Embodiment

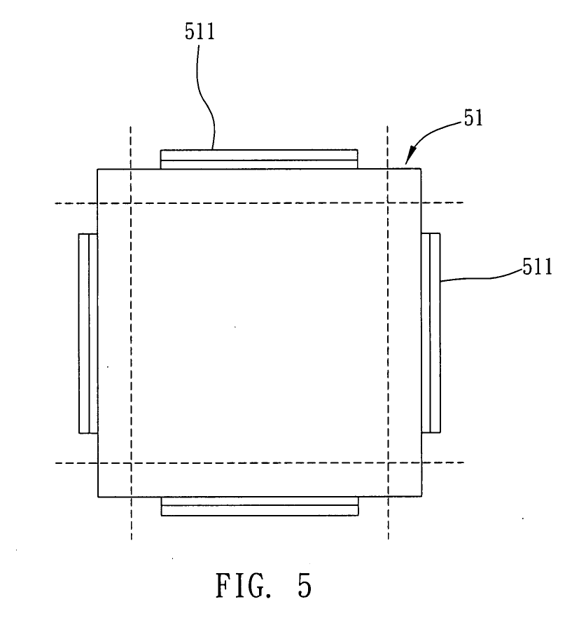

FIG. 5 is a top view showing a heat-dissipating structure fabricated according to a second embodiment of the present invention. Unlike the heat-dissipating structure 41 having the protruding portions 411 formed only at the corners thereof, the heat-dissipating structure 51 comprises a plurality of protruding portions formed at the corners and the middle of each edge thereof. Therefore, when the protruding portions 511 abut against the top surface of the mold cavity, arrangement and design as such allow the protruding portions 511 to add extra support to the heat-dissipating structure 51, so as to strengthen the heat-dissipating structure 51 during the molding process to eliminate warpage of the heat-dissipating structure effectively.

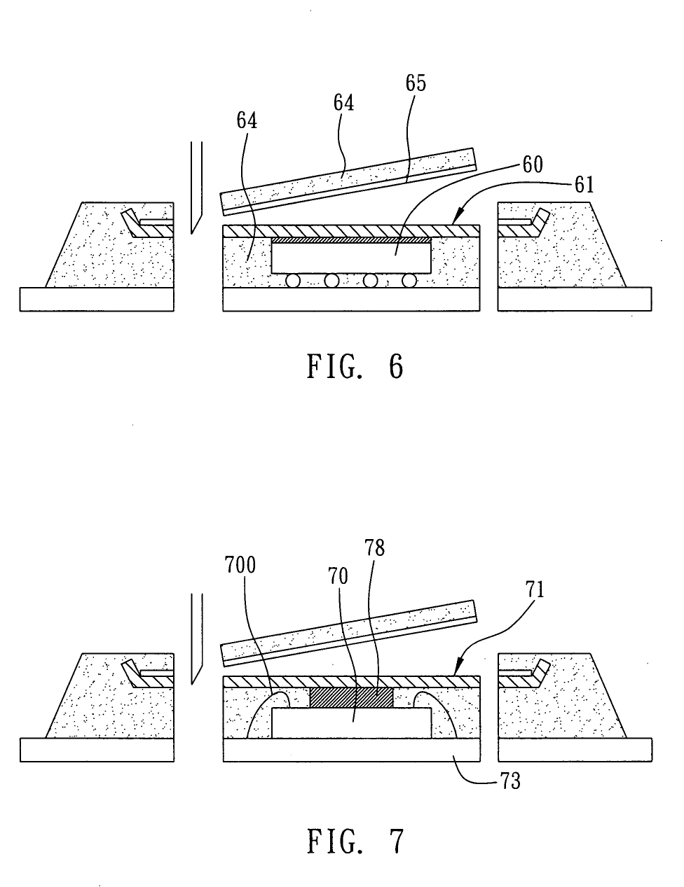

FIG. 6 is a schematic view showing a fabrication method of a heat-dissipating package according to the second embodiment of the present invention. The fabrication method disclosed in the second embodiment is similar to the first embodiment, except that the covering layer 65 of the heat-dissipating structure 61 may be made of at least one of a film, an epoxy material, and an organic layer such as a wax. During the removing process, said arrangement and design allow the adhesive force between the covering layer 65 and the encapsulant 64 to be relatively greater than the adhesive force between the covering layer 65 and the heat-dissipating structure 61, so that the covering layer 65 and the portion of the encapsulant 64 formed thereon can be removed from the heat-dissipating structure 61 in the mean time. As a result, a top surface of the heat-dissipating structure 61 is allowed to be exposed, and thus heat generated by the semiconductor 60 can be efficiently dissipated to the ambience via the top surface of the heat-dissipating structure 61.

### Third Embodiment

FIG. 7 is a schematic view showing a fabrication method of a heat-dissipating package according to a third embodiment of the present invention. As shown in FIG. 7, the fabrication method disclosed in this particular embodiment is similar to the aforementioned embodiments. What makes it different from the other embodiments is that a wire bond-type semiconductor chip 70 is employed in the third embodiment. The wire-bond type semiconductor chip 70 is mounted on a chip carrier 73 and electrically connected thereto via a plurality of bonding wires 700, and the wire-bond type semiconductor chip 70 may be attached with a spacer 78 made of a dummy chip or a heat-dissipating member, so that the heat-dissipating structure 71 can be mounted on the semiconductor chip 70 via the spacer 78 without touching the bonding wires 700.

To be concluded, the present invention mainly features in having a heat-dissipating structure with a covering layer formed on a surface thereof to be attached to a semiconductor chip, and edges of the heat-dissipating structure are formed with a plurality of protruding portions upwardly protruded from the main body of the heat-dissipating structure, and the size of the heat-dissipating structure is larger than a predetermined size of the heat-dissipating package. Therefore, while the chip carrier mounted with the semiconductor chip and the heat-dissipating structure thereon is placed in a mold cavity of a mold to be filled with EMC materials during a molding process, the protruding portions formed at edges of the heat-dissipating structure can abut against the top surface of the mold cavity to avoid warpage of the heat-dissipating structure, if the heat-dissipating structure is lifted by the bottom mold flow when the bottom mold flow below the heat-dissipating structure runs faster than the top mold flow thereabove. Accordingly, the present invention not only prevents warpage of the heat-dissipating structure and delamination of the heat-dissipating structure from the chip, but also improves the quality of electrical connection between the chip and the chip carrier without enlarging the mold cavity, thereby reducing the amount of material used and the cost of production. Once an encapsulant is formed, which covers the heat-dissipating structure and the chip, the mold is then removed and the package is cut according to a predetermined size. Subsequently, the portion of the encapsulant formed on the covering layer is removed, so that the heat-dissipating package integrated with the heat-dissipating structure is formed. Thus, the present invention not only solves drawbacks of the prior art, but also provides processes and configurations for highly efficient and economical manufacturing, application, and utilization.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hitherto fore set forth herein or shown in the accompanying drawings are to be interpreted in an illustrative and non-limiting sense.

What is claimed is:

1. A method for fabricating a heat-dissipating package, comprising the steps of:
mounting and electrically connecting a semiconductor chip to a chip carrier;
mounting a heat-dissipating structure to the semiconductor chip, wherein the heat-dissipating structure comprises a main body having a first surface that has a covering layer formed thereon, a second surface opposite to the first surface, and a plurality of protruding portions upwardly protruded from and formed at edges of the main body, and wherein a size of the heat-dissipating structure is larger than a predetermined size of the package, such that the edges of the main body of the heat-dissipating structure extend beyond corresponding sides of the semiconductor chip, after the heat-dissipating structure is attached to the semiconductor chip via the second surface of the main body thereof;
performing a molding process to form an encapsulant covering the heat-dissipating structure and the semiconductor chip, wherein the molding process includes disposing the chip carrier mounted with the semiconductor chip and the heat-dissipating structure into a mold cavity of a mold, filling the mold cavity with at least one packaging material, and removing the mold;
performing a singulation process to form the package with the predetermined size; and
performing a removing process to remove a portion of the encapsulant formed on the covering layer.

2. The fabrication method of claim 1, wherein the chip carrier is at least one of a substrate and a leadframe, and the semiconductor chip is electrically connected to the chip carrier via a flip-chip technique or wire-bonding technique.

3. The fabrication method of claim 1, wherein the protruding portions are to be disposed at a location outside the predetermined size of the package in plan view.

4. The fabrication method of claim 1, wherein the height of each of the protruding portions is about 0.03˜0.1 mm shorter than the vertical distance between the heat-dissipating structure and a top surface of the mold cavity.

5. The fabrication method of claim 1, wherein the height of each of the protruding portions is 0.05 mm shorter than the vertical distance between the heat-dissipating structure and the top surface of the mold cavity.

6. The fabrication method of claim 1, wherein during the molding process, when a bottom mold flow below the heat-dissipating structure has a relatively higher flow speed than a top mold flow thereabove, the heat-dissipating structure is lifted up, making that the protruding portions abut against the top surface of the mold cavity.

7. The fabrication method of claim 1, wherein the plurality of protruding portions are to be selectively disposed at any corner(s) and/or at the middle of any edge(s) of the heat-dissipating structure.

8. The fabrication method of claim 1, wherein an adhesive force between the covering layer and the heat-dissipating structure is greater than that between the covering layer and the encapsulant, allowing the portion of the encapsulant covering the covering layer to be capable of being removed to expose the covering layer during the removing process.

9. The fabrication method of claim 8, wherein the covering layer is a metal layer.

10. The fabrication method of claim 1, wherein an adhesive force between the covering layer and the encapsulant is greater than that between the covering layer and the heat-dissipating structure, allowing the covering layer and the portion of the encapsulant formed thereon to be capable of being removed at once during the removing process.

11. The fabrication method of claim 10, wherein the covering layer is at least one of a film, an epoxy material and an organic layer.

12. The fabrication method of claim 1, wherein the semiconductor chip is electrically connected to the chip carrier via a plurality of bonding wires and attached with the heat-dissipating structure via a spacer interposed therebetween.

13. The fabrication method of claim 12, wherein the spacer is at least one of a dummy chip and a heat-dissipating member.

14. A heat-dissipating structure, comprising:
a main body having a first surface and a second surface opposite to the first surface; and
a plurality of protruding portions formed at edges of the main body and upwardly protruded from the main body.

15. The heat-dissipating structure of claim 14, wherein the plurality of protruding portions are selectively disposed at any corner(s) and/or at the middle of any edge(s) of the heat-dissipating structure.

16. The heat-dissipating structure of claim 14, further comprising a covering layer applied on the first surface of the main body.

17. The heat-dissipating structure of claim 16, wherein an adhesive force between the covering layer and the heat-dissipating structure is greater than that between the covering layer and the encapsulant.

18. The heat-dissipating structure of claim 17, wherein the covering layer is a metal layer.

19. The heat-dissipating structure of claim 16, wherein an adhesive force between the covering layer and the encapsulant is greater than that between the covering layer and the heat-dissipating structure.

20. The heat-dissipating structure of claim 19, wherein the covering layer is at least one of a film, an epoxy material and an organic layer.
